(19) United States
(12) Patent Application Publication
(10) Pub. No.: US 2024/0085787 A1
(43) Pub. Date: Mar. 14, 2024

(54) PHOTOSENSITIVE PASTE, METHOD FOR FORMING WIRING PATTERN, METHOD FOR PRODUCING ELECTRONIC COMPONENT, AND ELECTRONIC COMPONENT

(71) Applicant: Murata Manufacturing Co., Ltd., Kyoto-fu (JP)

(72) Inventor: Isamu MIYAKE, Nagaokakyo-shi (JP)

(73) Assignee: Murata Manufacturing Co., Ltd., Kyoto-fu (JP)

(21) Appl. No.: 18/347,982

(22) Filed: Jul. 6, 2023

(30) Foreign Application Priority Data
Aug. 30, 2022 (JP) 2022-137134

(51) Int. Cl. G03F 7/029; G03F 7/004; G03F 7/34; G03F 7/40; H01F 27/28; H01F 27/32; H01F 41/12

(52) U.S. Cl. CPC G03F 7/029; G03F 7/0045; G03F 7/34; G03F 7/40; H01F 27/2823; H01F 27/323; H01F 41/122

(57) ABSTRACT

A photosensitive paste contains a photoinitiator, a photopolymerizable monomer, an alkali-soluble polymer, an inorganic powder, and a radical scavenger. A method for forming a wiring pattern includes a step of forming a photosensitive paste film by applying the photosensitive paste that has electrical conductivity to an insulating sheet; a step of irradiating a portion of the photosensitive paste film with an active energy ray; and a step of forming a wiring pattern by removing an uncured portion of the photosensitive paste film.

### CROSS-REFERENCE TO RELATED APPLICATION

This application claims benefit of priority to Japanese Patent Application No. 2022-137134, filed Aug. 30, 2022, the entire content of which is incorporated herein by reference.

### BACKGROUND

### Technical Field

The present disclosure relates to a photosensitive paste, a method for forming a wiring pattern, a method for producing an electronic component, and an electronic component.

### Background Art

A photosensitive paste typically contains a photopolymerizable monomer and a photoinitiator (for example, International Publication No. WO 2018/016480). When the photosensitive paste is irradiated with an active energy ray, the photoinitiator generates radicals. Radicals rapidly add to the photopolymerizable monomer to generate monomer radicals. As a result, a polymerization reaction is initiated. The monomer radicals are continuously generated, and a polymer (cured product) derived from the photopolymerizable monomer eventually forms.

When forming a wiring pattern by using a photosensitive paste, the photosensitive paste is applied to an insulating layer, and then a portion of the applied photosensitive paste is irradiated with an active energy ray. The photopolymerizable monomer contained in the exposed portion of the photosensitive paste becomes polymerized and cured. Then the uncured remainder of the photosensitive paste is removed. As a result, a particular wiring pattern is formed on the insulating layer.

### SUMMARY

However, monomer radicals occur in and spread to portions other than the portion irradiated with the active energy ray, and thus the polymerization reaction can also progress in such portions. As a result, a wiring pattern thicker than what is desirable is formed.

Accordingly, the present disclosure provides a photosensitive paste that can form a desired shape at high accuracy. Also, the present disclosure provides a method for forming a wiring pattern and a method for forming an electronic component by using the photosensitive paste, and an electronic component.

According to an aspect of the present disclosure addressing the issue described above, there is provided a photosensitive paste containing:
a photoinitiator;
a photopolymerizable monomer;
an alkali-soluble polymer;
an inorganic powder; and
a radical scavenger.

According to this aspect, when performing patterning using a photosensitive paste, diffusion of monomer radicals in the in-plane direction of the photosensitive paste-coated surface is reduced, and thus a desired shape can be formed at high accuracy.

According to another aspect of the present disclosure, there is provided a method for forming a wiring pattern, the method including a step of forming a photosensitive paste film by applying the photosensitive paste that has electrical conductivity to an insulating sheet; a step of irradiating a portion of the photosensitive paste film with an active energy ray; and a step of forming a wiring pattern by removing an uncured portion of the photosensitive paste film.

According to this aspect, a wiring pattern having a desired shape is obtained.

According to yet another aspect of the present disclosure, there is provided a method for producing an electronic component, the method including a step of forming a photosensitive paste film by applying the photosensitive paste that has electrical conductivity to an insulating sheet; a step of irradiating a portion of the photosensitive paste film with an active energy ray; a step of forming a wiring pattern by removing an uncured portion of the photosensitive paste film; a step of stacking an insulating sheet on the wiring pattern; and a step of firing the wiring pattern and the insulating sheets to obtain of insulating layers as sintered bodies of the insulating sheets and an inner wire as a sintered body of the wiring pattern.

According to this aspect, an electronic component having highly accurate internal wiring is obtained.

According to still another aspect of the present disclosure, there is provided an electronic component including an element body including insulating layers; and an inner wire that is a sintered body of a cured product of the photosensitive paste according to Claim 2, the inner wire being disposed in the element body.

According to this aspect, an electronic component having excellent performance and reliability is obtained.

According to the photosensitive paste of the present disclosure, a desired shape can be formed at high accuracy. Furthermore, an electronic component obtained by using the photosensitive paste of the present disclosure has excellent performance and reliability.

### BRIEF DESCRIPTION OF THE DRAWINGS

FIG. 1 is a schematic perspective view of an electronic component; and

FIG. 2 is a schematic exploded perspective view of the electronic component.

### DETAILED DESCRIPTION

A photosensitive conductive paste, a method for forming a wiring pattern, a method for producing an electronic component, and an electronic component which are embodiments of the present disclosure will now be described in further detail through embodiments illustrated in the drawings. Note that the drawings may be partly schematic and do not always faithfully represent actual dimensions and proportions.

### First Embodiment

### Electronic Component

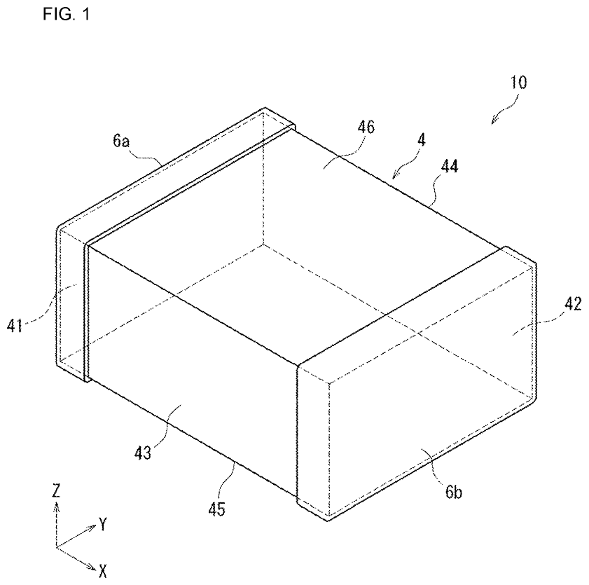

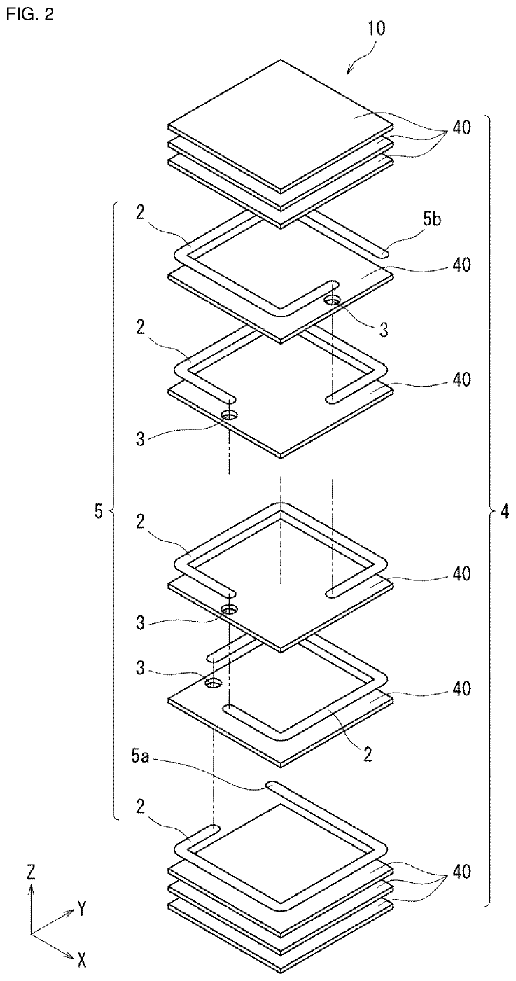

FIG. 1 is a schematic perspective view of an electronic component. FIG. 2 is a schematic exploded perspective view of the electronic component. Although an element body in FIG. 1 is illustrated as transparent to facilitate the understanding of the structure, the element body may be translucent or opaque. In FIG. 1, depiction of the coil is omitted to facilitate the understanding of the structure. In FIG. 2, depiction of outer electrodes are omitted to promote visibility.

Although a multilayer coil component is described below as an example of the electronic component, the electronic component of the present disclosure is not limited to this and can be applied to various electronic components such as capacitor components and LC combined components.

As illustrated in FIGS. 1 and 2, a multilayer coil component 10 includes an element body 4, a coil 5 disposed inside the element body 4, and a first outer electrode 6a and a second outer electrode 6b attached to the element body 4.

The shape of the element body 4 is not particularly limited, and is substantially rectangular parallelepiped in this embodiment. Outer surfaces of the element body 4 are a first end surface 41, a second end surface 42 opposing the first end surface 41, a first side surface 43 that connects the first end surface 41 and the second end surface 42, a second side surface 44 opposing the first side surface 43, a bottom surface 45 that connects the first end surface 41, the second end surface 42, the first side surface 43, and the second side surface 44, and a top surface 46 that opposes the bottom surface 45 and connects to the first end surface 41, the second end surface 42, the first side surface 43 and the second side surface 44. A direction that extends from the first end surface 41 to the second end surface 42 is the X direction, a direction that extends from the first side surface 43 to the second side surface 44 is the Y direction, and a direction that extends from the bottom surface 45 to the top surface 46 is the Z direction. In this description, the Z direction may be referred to as the upper side.

The element body 4 is constituted by stacking multiple insulating layers 40. The insulating layers 40 correspond to one example of a sintered body of the “insulating sheet” recited in the claims. The material for the insulating sheet is not particularly limited, and, for example, contains borosilicate glass and an inorganic powder. The direction in which the insulating layers 40 are stacked is a direction parallel to the Z direction. In other words, the insulating layers 40 are layers that spread across the XY plane. “Parallel” is not limited to a strict parallel relationship, and includes substantially parallel relationships in view of realistic ranges of variations. The interfaces between the insulating layers 40 in the element body 4 may be indistinctive due to firing or the like.

The coil 5 includes multiple coil wires 2 stacked along the axis direction, and via wires (not illustrated) that extend in the axis direction and connect coil wires 2 adjacent in the axis direction to each other. The coil wires 2 are each wound along the flat surface and are arranged to align in the axis direction so that the coil wires 2 are electrically connected in series and constitute a spiral. The coil wires 2 are formed by using an electrically conductive photosensitive paste (photosensitive conductive paste). The coil wires 2 correspond to one example of the “internal wire” recited in the claims. The coil wires 2 and the “inner wire” correspond to one example of a sintered body of the “wiring pattern” or the cured electrically conductive “photosensitive paste” recited in the claims.

Although the coil 5 has a square shape when viewed in the axis direction, the shape is not limited to this. The shape of the coil 5 may be circular, elliptic, rectangular, polygonal, or the like. The axis direction of the coil 5 is parallel to the Z direction, and the coil 5 is wound along the axis direction. The axis of the coil 5 refers to the center axis of the spiral shape of the coil 5.

The coil 5 is spirally wound along the stacking direction of the insulating layers 40. A first end 5a of the coil 5 is exposed from the first end surface 41 of the element body 4 and is connected to the first outer electrode 6a. A second end 5b of the coil 5 is exposed from the second end surface 42 of the element body 4 and is connected to the second outer electrode 6b.

Each of the coil wires 2 is wound on the main surface (XY plane) of the insulating layer 40 orthogonal to the axis direction. The number of windings of the coil wire 2 is less than 1, but can be 1 or more. The via wires are formed in the via holes 3 in the insulating layers 40 and penetrate through the insulating layers 40 in the thickness direction (Z direction). The coil wires 2 that are adjacent to each other in the stacking direction are thereby electrically connected in series via the via wires.

The insulating layer 40 located between each two adjacent coil wires 2 has a via hole 3 at a position where the adjacent coil wires 2 connect to each other. The via hole 3 penetrates the insulating layer 40 in the thickness direction (Z direction).

The multilayer coil component 10 that includes the element body 4 and the coil 5 disposed inside the element body 4 is obtained by a method that involves forming a wiring pattern by photolithography using a photosensitive paste. First, a photosensitive conductive paste is applied to an insulating sheet to form a photosensitive paste film. After one portion of the photosensitive paste film is irradiated with an active energy ray, the uncured portion of the photosensitive paste film is removed (developed) to form a wiring pattern. Another insulating sheet is then placed on the wiring pattern. As such, insulating sheets and wiring patterns formed of the photosensitive conductive paste are alternately stacked to obtain a multilayer structure. Lastly, the multilayer structure is fired to obtain a coil 5 that includes an element body 4 that includes multiple insulating layers 40 as the sintered bodies of the insulating sheets, and multiple coil wires 2 that are disposed inside the element body 4 and that are obtained as sintered bodies of the wiring patterns.

The first outer electrode 6a and the second outer electrode 6b are made of a conductive material such as Ag, Cu, Au, or an alloy containing any one of these as a main component. In this embodiment, the first outer electrode 6a is continuously formed on the entire surface of the first end surface 41 of the element body 4, an end portion of the first side surface 43 close to the first end surface 41, an end portion of the second side surface 44 close to the first end surface 41, an end portion of the bottom surface 45 close to the first end surface 41, and an end portion of the top surface 46 close to the first end surface 41. The second outer electrode 6b is continuously formed on the entire surface of the second end surface 42 of the element body 4, an end portion of the first side surface 43 close to the second end surface 42, an end portion of the second side surface 44 close to the second end surface 42, an end portion of the bottom surface 45 close to the second end surface 42, and an end portion of the top surface 46 close to the second end surface 42. In short, each of the first outer electrode 6a and the second outer electrode 6b is a five-surface electrode. However, this feature is not limiting, and, for example, the first outer electrode 6a may be an L-shaped electrode that is continuously formed on one portion of the first end surface 41 and one portion of the bottom surface 45. Similarly, the second outer electrode 6b may be an L-shaped electrode that is continuously formed on one portion of the second end surface 42 and one portion of the bottom surface 45.

### Photosensitive Paste

Next, detailed features of the photosensitive conductive paste used in forming the coil 5 are described. The photosensitive conductive paste refers to a photosensitive paste that has electrical conductivity. The photosensitive paste according to the present disclosure is not limited to the one having electrical conductivity and may be the one having no electrical conductivity.

The photosensitive paste according to the present disclosure contains a photoinitiator, a photopolymerizable monomer, an alkali-soluble polymer, an inorganic powder, and a radical scavenger. The photosensitive paste according to the present disclosure is of a negative type that contains a monomer polymerizable by an active energy ray. Hereinafter, the components of the photosensitive paste other than the inorganic powder and the radical scavenger may be referred to as the photosensitive resin composition.

When forming a wiring pattern on an insulating sheet by photolithography, the radical scavenger reduces excessive diffusion of generated monomer radicals particularly along the main surface direction of the insulating sheet. As a result, the desired wiring pattern is formed at high accuracy, and the coil wire 2 obtained by firing the wiring pattern is also formed at high accuracy. Hereinafter, formation of the desired shape by photolithography at high accuracy may be referred to as having excellent resolution.

Hereinafter, a “hydrocarbon group” refers to a group that contains carbon and hydrogen in which one hydrogen atom is desorbed from a hydrocarbon. Examples of the hydrocarbon group include aliphatic hydrocarbon groups and aromatic hydrocarbon groups having 1 to 20 carbon atoms. The aliphatic hydrocarbon group may be linear, branched, or cyclic, and may be saturated or unsaturated. The hydrocarbon group may include one or more cyclic structures. Representative examples of the hydrocarbon group include an alkyl group, an alkoxy group, an alkenyl group, an alkynyl group, a cycloalkyl group, an unsaturated cycloalkyl group, a heterocyclyl group, and an unsaturated heterocyclyl group.

The hydrocarbon group may have, at a terminal or in a molecular chain, one or more N, O, S, Si, amino bonds, carbonyl structures (—C(═O)—), or carbonyloxy structures (—O—C(═O)—).

One or more hydrogen atoms in the hydrocarbon group may each be substituted with a substituent. Examples of the substituent include a halogen atom, a carboxy group, an amino group, an alkyl group having 1 to 6 carbon atoms, an alkoxy group having 1 to 6 carbon atoms, an alkenyl group having 2 to 6 carbon atoms, an alkynyl group having 2 to 6 carbon atoms, a cycloalkyl group having 3 to 10 carbon atoms, an unsaturated cycloalkyl group having 3 to 10 carbon atoms, a 5 to 10-membered heterocyclyl group, a 5 to 10-membered unsaturated heterocyclyl group, an aryl group having 3 to 10 carbon atoms, and a 5 to 10-membered heteroaryl group. The substituent may be in a side chain or at a terminal of the hydrocarbon group.

Examples of the halogen atom include fluorine (F), chlorine (Cl), bromine (Br), iodine (I), and astatine (At).

Examples of the alkyl group having 1 to 6 carbon atoms include a methyl group, an ethyl group, an n-propyl group, an isopropyl group, an n-butyl group, a tert-butyl group, an n-pentyl group, a neopentyl group, an isopentyl group, a 3-pentyl group, an n-hexyl group, and an isohexyl group.

Examples of the alkoxy group having 1 to 6 carbon atoms include a methoxy group, an ethoxy group, a propoxy group, an isopropoxy group, a butoxy group, a pentyloxy group, a hexyloxy group, and isomers thereof.

The amino group may be primary (—NH₂), secondary (—NHR_{N}), or tertiary (—NR^{N}R^{N′}). N^{N} and N^{N′} each independently represent an alkyl group having 1 to 6 carbon atoms, for example.

### Radical Scavenger

The radical scavenger efficiently traps alkyl radicals (R·) and peroxy radicals (ROO·) generated by active energy ray irradiation. The radical scavenger is also referred to as a polymerization inhibitor, a photostabilizer, or an antioxidant.

The radical scavenger content may be 0.01 mass % or more or 0.1 mass % or more of the photosensitive paste. The radical scavenger content may be 5 mass % or less or 1 mass % or less of the photosensitive paste. In one embodiment, the radical scavenger content is 0.01 mass % or more and 5 mass % or less (i.e., from 0.01 mass % to 5 mass % or less) of the photosensitive paste.

The radical scavenger may be any compound that can trap radicals. For example, the radical scavenger may be at least one selected from the group consisting of a radical scavenger having a phenol structure, a radical scavenger having a benzotriazole structure, and a radical scavenger having a hindered amine structure.

In this embodiment, the radical scavenger has a phenol structure. A radical scavenger that has a phenol structure (hereinafter may be referred to as a phenol radical scavenger) facilitates removal of the inorganic powder along with the uncured photopolymerizable monomer during development.

### Phenol Radical Scavenger

The phenol structure has a benzene ring and at least one hydroxyl group bonded to the benzene ring. The number of phenol structures in one molecule is 1 or more and may be 2 or more. When two or more phenol structures are present, they may be the same or different.

The phenol radical scavenger is, for example, represented by general formula below:

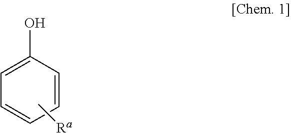

(In the formula, R^{a} represents one or more and five or less groups bonded to the benzene ring, and these groups may each independently represent a hydrogen atom, a hydroxyl group, a hydrocarbon group, a carboxy group, an amino group, or a halogen atom.)

One or more R^{a} are bonded to the benzene ring, and two or more R^{a} may be bonded to the benzene ring. Five or less R^{a} are bonded to the benzene ring, and four or less R^{a} may be bonded to the benzene ring. When two or more R^{a} are present, they may be the same or different.

At least one R^{a} may be a hydroxyl group. In other words, the phenol radical scavenger may have two or more hydroxyl groups bonded to the benzene ring.

R^{a} may have an alkyl ester group (—C(═O)O—R^{a1}). R^{a1} is, for example, an alkyl group having 1 to 20 carbon atoms. The alkyl ester group may be directly bonded to the benzene ring, and, for example, may be bonded to the benzene ring via an alkyl group having 1 to 6 carbon atoms.

R^{a} may have a thioalkyl group (—SR^{a2}). Rₐ₂ is, for example, an alkyl group having 1 to 20 carbon atoms. The thioalkyl group may be directly bonded to the benzene ring, and, for example, may be bonded to the benzene ring via an alkyl group having 1 to 6 carbon atoms.

At least one R^{a} may be a hydrocarbon group. At least one R^{a} may be an alkoxy group, an alkoxy group having 1 to 6 carbon atoms, or a methoxy group. At least one R^{a} may be an alkyl group, an alkyl group having 1 to 6 carbon atoms, or a tert-butyl group. A phenol radical scavenger having at least one tert-butyl group is also referred to as a hindered phenol.

The hindered phenol is, for example, represented by general formula below:

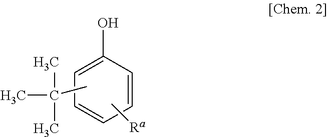

(In the formula, R^{a} is the same as above.)

Examples of the phenol radical scavenger include phenol, catechol, pyrogallol, 1,2,4-trihydroxybenzene, phloroglucinol, resorcinol, homocatechol, p-cresol, 2,4-dimethylphenol, 2,6-dimethylphenol, 4,6-bis(dodecylthiomethyl)-o-cresol, and 4,6-bis(octylthiomethyl)-o-cresol.

Examples of the phenol radical scavenger having an alkoxy group include 2-methoxyphenol, 4-methoxyphenol, and 2,6-dimethoxyphenol.

Examples of the hindered phenol include 2,6-di-tert-butyl-4-methylphenol, 2,5-di-tert-butylbenzene-1,4-diol, tert-butylhydroxyanisole, pentaerythritol tetrakis[3-(3,5-di-tert-butyl-4-hydroxyphenyl)propionate], thiodiethylenebis[3-(3,5-di-tert-butyl-4-hydroxyphenyl)propionate], octadecyl-3-(3,5-di-tert-butyl-4-hydroxyphenyl)propionate, N,N′-hexane-1,6-diylbis[3-(3,5-di-tert-butyl-4-hydroxyphenyl)propionamide], 3,3′,3″,5,5′,5″-hexa-tert-butyl-a,a′,a″-(mesitylene-2,4,6-triyl)tri-p-cresol, ethylenebis(oxyethylene)bis[3-(5-tert-butyl-4-hydroxy-m-tolyl)propionate], hexamethylenebis[3-(3,5-di-tert-butyl-4-hydroxyphenyl)propionate], 1,3,5-tris(3,5-di-tert-butyl-4-hydroxybenzyl)-1,3,5-triazine-2,4,6(1H,3H,5H)-trione, 1,3,5-tris[(4-tert-butyl-3-hydroxy-2,6-dimethylbenzyl)methyl]-1,3,5-triazine-2,4,6(1H,3 H,5H)-trione, and 2,6-di-tert-butyl-4-[4,6-bis(octylthio)-1,3,5-triazin 2-ylamino]phenol

### Photoinitiator

The photoinitiator generates highly reactive radicals when irradiated with an active energy ray. Radicals rapidly add to the photopolymerizable monomer and induce the initiation reaction of the photopolymerizable monomer. Radicals are generated in a chain reaction fashion, and a polymer derived from the photopolymerizable monomer eventually forms.

The photoinitiator content may be 1 mass % or more or 2 mass % or more of the photosensitive resin composition. The photoinitiator content may be 10 mass % or less or 5 mass % or less of the photosensitive resin composition. In one embodiment, the photoinitiator content is 1 mass % or more and 10 mass % or less (i.e., from 1 mass % to 10 mass %) of the photosensitive resin composition.

The photoinitiator may be, for example, at least one selected from the group consisting of benzoin or a benzoin ether compound, an alkylphenone compound, a benzophenone compound, an oxime ester compound, an acylphosphine oxide compound, and an α-ketoester compound.

Examples of the benzoin or benzoin ether photoinitiator include benzoin, benzoin ethyl ether, benzoin isopropyl ether, benzoin phenyl ether, methyl benzoin, ethyl benzoin, and benzyl dimethyl ketal.

Examples of the alkylphenone photoinitiator include α-hydroxyalkylphenone compounds and α-aminoalkylphenone compounds.

Specific examples of the α-aminoalkylphenone compound include 2-methyl-1-(4-methylthiophenyl)-2-morpholinopropan-1-one, 2-benzyl-2-dimethylamino-1-(4-morpholinophenyl)-butanone-1, 2-(dimethylamino)-2-[(4-methylphenyl)methyl]-1-[4-(4-morpholinyl)phenyl]-1-butanone, and 2-methyl-2-morpholino(4-thiomethylphenyl)propan-1-one.

Specific examples of α-hydroxyalkylphenone compound include 2-hydroxy-2-methylpropiophenone, diethoxyacetophenone, 4-(2-hydroxyethoxy)phenyl-(2-hydroxy-2-propyl)ketone, 2-hydroxy-2-methyl-1-phenyl-propan-1-one, 1-hydroxy-cyclohexyl-phenylketone, 2,2-dimethoxy-1,2-diphenylethan-1-one, 2-hydroxy-2-methyl-1-phenylpropan-1-one, 1-(4-dodecylphenyl)-2-hydroxy-2-methylpropan-1-one, 1-{4-(2-hydroxyethoxy)-phenyl}-2-hydroxy-2-methyl-1-propan-1-one, 2-hydroxy-1-{4-[4-(2-hydroxy-2-methyl-propionyl)-benzyl]phenyl}-2-methylpropan-1-one, 1,1-(oxybis(4,1-phenylene))bis(2-hydroxy)-2-methylpropan-1-one, 2,2-dimethoxy-2-phenylacetophenone, oligo{2-hydroxy-2-methyl-1-[4-(1-methylvinyl)phenyl]propane}, and 4-(2-acryloyl-oxyethoxy)phenyl-2-hydroxy-2-propylketone.

Examples of the benzophenone photoinitiator include benzophenone, methylbenzophenone, benzoylbenzoic acid, methyl o-benzoylbenzoate, 2-n-butoxy-4-dimethylaminobenzoate, 2-dimethylaminoethylbenzoate, ethyl p-dimethylaminobenzoate, isoamyl p-dimethylaminobenzoate, 4-phenylbenzophenone, 4,4′-bisdiethylaminobenzophenone, 3,3′-dimethyl-4-methoxybenzophenone, (1-[4-(4-benzoylphenylsulfanyl)phenyl]-2-methyl-2-(4-methylphenylsulfonyl)propan-1-one, 4-(4-methylphenythio)benzophenone, methyl-o-benzoylbenzoate, 4,4′-dichlorobenzophenone, hydroxybenzophenone, 4-benzoyl-4′-methyl-diphenyl sulfide, acrylated benzophenone, 3,3′,4,4′-tetra(t-butylperoxycarbonyl)benzophenone, 3,3′-dimethyl-4-methoxybenzophenone, thioxanthone initiators such as 2-isopropylthioxanthone, 2,4-dimethylthioxanthone, 2-chlorothioxanthone, 2,4-diethylthioxanthone, 2,4-dimethylthioxanthone, 2,4-diisopropylthioxanthone, isopropylthioxanthone, and 2,4-dichlorothioxanthone, Michler's ketone, 4,4′-bisdiethylaminobenzophenone, 3,3′,4,4′-tetra(t-butylperoxycarbonyl)benzophenone, and benzophenone derivative polymers.

Examples of the oxime ester photoinitiator include 1,2-octanedione, 1-[4-(phenylthio)phenyl]-, 2-(O-benzoyloxime), 1-phenyl-1,2-propanedione-2-(o-ethoxycarbonyl)oxime, and ethanone, 1-[9-ethyl-6-(2-methylbenzoyl)-9H-carbazol-3-yl]-, 1-(O-acetyloxime).

Examples of the acylphosphine oxide photoinitiator include 2,4,6-trimethylbenzoyl-diphenylphosphine oxide, bis(2,4,6-trimethylbenzoyl)-phenylphosphine oxide, bis(2,6-dimethoxybenzoyl)-2,4,4-trimethylpentylphosphine oxide, and ethyl (2,4,6-trimethylbenzoyl)-phenylphosphinate.

Examples of the α-ketoester photoinitiator include methyl benzoyl formate, 2-(2-oxo-2-phenylacetoxyethoxy)ethyl ester of oxyphenylacetic acid, and 2-(2-hydroxyethoxy)ethyl ester of oxyphenylacetic acid.

The photoinitiator may be an alkylphenone compound, an α-aminoalkylphenone compound, or 2-methyl-1-(4-methylthiophenyl)-2-morpholinopropan-1-one.

### Photopolymerizable Monomer

The photopolymerizable monomer generates monomer radicals upon reacting with the photoinitiator. The monomer radicals are polymerized and generate a polymer.

The photopolymerizable monomer content may be 5 mass % or more or 10 mass % or more of the photosensitive resin composition. The photopolymerizable monomer content may be 35 mass % or less or 25 mass % or less of the photosensitive resin composition. In one embodiment, the photopolymerizable monomer content is 5 mass % or more and 35 mass % or less (i.e., from 5 mass % to 35 mass %) of the photosensitive resin composition.

The photopolymerizable monomer is not particularly limited as long as at least one reactive group that undergoes radical reaction is included. The radically reactive group is, for example, at least one selected from the group consisting of an acrylamide group, an acryloyl group, a methacryloyl group, an allyl group, a vinyl group, a styryl group, and a mercapto group. The photopolymerizable monomer may have at least one (meth)acryloyl group as the radically reactive group. The “(meth)acryloyl group” refers to an acryloyl group and/or a methacryloyl group.

Examples of the photopolymerizable monomer that has a (meth)acryloyl group include monofunctional (meth)acrylate monomers such as stearyl (meth)acrylate, tetrahydrofurfuryl (meth)acrylate, lauryl (meth)acrylate, 2-phenoxyethyl (meth)acrylate, isodecyl (meth)acrylate, isooctyl (meth)acrylate, tridecyl (meth)acrylate, caprolactone (meth)acrylate, and ethoxylated nonylphenol (meth)acrylate; difunctional (meth)acrylate monomers such as tripropylene glycol di(meth)acrylate, isocyanuric acid EO-modified diacrylate, 1,3-butanediol di(meth)acrylate, 1,4-butanediol di(meth)acrylate, diethylene glycol di(meth)acrylate, tetraethylene glycol di(meth)acrylate, triethylene glycol di(meth)acrylate, ethoxylated bisphenol A di(meth)acrylate, and propoxylated neopentyl glycol di(meth)acrylate; trifucntional (methacrylate monomers such as glycerin tri(meth)acrylate, trimethylolpropane tri(meth)acrylate, ethoxylated trimethylolpropane tri(meth)acrylate, propoxylated trimethylolpropane tri(meth)acrylate, propoxylated glyceryl tri(meth)acrylate, pentaerythritol tri(meth)acrylate, dipentaerythritol tri(meth)acrylate, ethoxylated pentaerythritol tri(meth)acrylate, tris(2-hydroxyethyl)isocyanurate tris(2-hydroxyethyl)isocyanurate tri(meth)acrylate, caprolactone-modified tri(meth)acrylate, hexanediol tri(meth)acrylate, tripropylene glycol tri(meth)acrylate, trimethylolpropane tri(meth)acrylate, and EO-modified trimethylolpropane tri(meth)acrylate; tetrafunctional (meth)acrylate monomers such as pentaerythritol tetra(meth)acrylate, dipentaerythritol tetra(meth)acrylate, tripentaerythritol tetra(meth)acrylate, ditrimethylolpropane tetra(meth)acrylate, and ethoxylated pentaerythritol tetra(meth)acrylate; pentafunctional (meth)acrylate monomers such as penta(meth)acrylate, and dipentaerythritol penta(meth)acrylate, tripentaerythritol dipentaerythritol monohydroxypenta(meth)acrylate; hexafunctional (meth)acrylate monomers such as dipentaerythritol hexa(meth)acrylate, caprolactone-modified dipentaerythritol hexa(meth)acrylate, and tripentaerythritol hexa(meth)acrylate; and hepta- or higher functional (meth)acrylate monomers such as tripentaerythritol hepta(meth)acrylate and tripentaerythritol octa(meth)acrylate.

The photopolymerizable monomer may be a trifunctional or higher (meth)acrylate monomer, may be a tetrafunctional or higher (meth)acrylate monomer, or may be a pentafunctional or higher (meth)acrylate monomer. The photopolymerizable monomer may be dipentaerythritol monohydroxypenta(meth)acrylate.

### Alkali-Soluble Polymer

The alkali-soluble polymer is neutralized with a basic compound and becomes soluble. The alkali-soluble polymer is removed along with the uncured photopolymerizable monomer, the inorganic powder, etc., during a development process that uses an alkaline chemical. Meanwhile, when the photopolymerizable monomer polymerizes due to an active energy ray, the alkali-soluble polymer near the photopolymerizable monomer forms a film together with a polymer of the photopolymerizable monomer and forms part of the wiring pattern. As a result, the adhesion of the wiring pattern to the insulating sheet can be improved.

The alkali-soluble polymer content may be 0.5 mass % or more or 2 mass % or more of the photosensitive resin composition. The alkali-soluble polymer content may be 50 mass % or less or 40 mass % or less of the photosensitive resin composition. In one embodiment, the alkali-soluble polymer content is 0.5 mass % or more and 50 mass % or less (i.e., from 0.5 mass % to 50 mass %) of the photosensitive resin composition.

The alkali-soluble polymer has at least one acid group in a side chain. A typical example of the acid group is a carboxy group. The main chain of the alkali-soluble polymer includes a polymer chain that has at least one selected from a carbon-carbon bond, an ether bond, a urea bond, an ester bond, and a urethane bond. From the viewpoint of transparency, the main chain of the alkali-soluble polymer may include a polymer chain that has a carbon-carbon bond.

An alkali-soluble polymer that has at least one carboxy group in a side chain and that has a main chain including a polymer chain having a carbon-carbon bond is obtained by copolymerization of an ethylenically unsaturated carboxylic acid and an ethylenically unsaturated compound. A typical example of the alkali-soluble polymer is a carboxy group-containing acrylic polymer.

Examples of the ethylenically unsaturated carboxylic acid include acrylic acid, methacrylic acid, crotonic acid, maleic acid, fumaric acid, itaconic acid, vinylacetic acid, and dimers and anhydrides thereof.

Examples of the ethylenically unsaturated compound include acrylic acid esters such as methyl acrylate, ethyl acrylate, butyl acrylate, isobutyl acrylate, t-butyl acrylate, 2-ethylhexyl acrylate, lauryl acrylate, and isobornyl acrylate; methacrylic acid esters such as methyl methacrylate, ethyl methacrylate, butyl methacrylate, isobutyl methacrylate, t-butyl methacrylate, 2-ethylhexyl methacrylate, lauryl methacrylate, and isobornyl methacrylate; fumaric acid esters such as monoethyl fumarate; and styrene.

The carboxy group of the alkali-soluble polymer may be introduced after formation of the main chain. The carboxy group of the alkali-soluble polymer may be introduced by, for example, causing a compound having the aforementioned polymer chain and a side chain having an epoxy group to react with an unsaturated monocarboxylic acid and then causing the resulting product to react with an anhydride of a saturated or unsaturated polycarboxylic acid.

The alkali-soluble polymer may have an unsaturated bond. Since the alkali-soluble polymer also functions as a polymerization component in this case, the adhesion of the wiring pattern to the insulating sheet can be further improved. The unsaturated bond of the alkali-soluble polymer may be introduced by, for example, adding, to the carboxyl group in the side chain, a monomer that can react with the carboxyl group and that has a polymerizable functional group (typically, an epoxy group).

The weight-average molecular weight (Mw) of the alkali-soluble polymer may be 10000 or more and 50000 or less (i.e., from 10000 to 50000). The acid value of the alkali-soluble polymer may be 30 or more and 150 or less (i.e., from 30 to 150).

### Inorganic Powder

The inorganic powder reduces shrinkage of the wiring pattern during the active energy ray irradiation step and the firing step. The inorganic powder can also impart various functions to the photosensitive paste. For example, the photosensitive conductive paste used in forming the coil 5 contains an electrically conductive inorganic powder (typically, a metal powder described below), and the photosensitive paste exhibits electrical conductivity due to this powder.

The inorganic powder content may be 68 mass % or more or 72 mass % or more of the photosensitive paste. The inorganic powder content may be 88 mass % or less or 85 mass % or less of the photosensitive paste. In one embodiment, the inorganic powder content is 68 mass % or more and 88 mass % or less (i.e., from 68 mass % to 88 mass %) of the photosensitive paste.

The average particle size of the inorganic powder is not particularly limited. From the viewpoint of forming fine wires, the average particle size of the inorganic powder may be 5.0 μm or less. The average particle size of the inorganic powder may be 1.0 μm or more.

The average particle size of the inorganic powder is obtained as a volume-based median (D50) from a particle size distribution in the range of 0.02 μm or more and 1400 μm or less (i.e., from 0.02 μm to 1400 μm) obtained by a laser diffraction/scattering method with a particle size distribution analyzer (for example, MT3300-EX produced by MicrotracBEL Corp.).

The inorganic powder can be rephrased as “particles free of carbon atoms (C)”. The inorganic powder is not particularly limited, and can be selected according to the purpose, as appropriate. The inorganic powder is, for example, at least one selected from the group consisting of a metal powder, a glass powder, and a ceramic powder.

Examples of the material for the metal powder include silver (Ag), copper (Cu), gold (Au), platinum (Pt), lead (Pd), nickel (Ni), tungsten (W), aluminum (Al), and molybdenum (Mo). These may be used alone or in combination. In particular, the metal powder may be a Ag powder or a Cu powder.

The material for the glass powder is, for example, a known glass such as borosilicate glass. Specific examples of the material for the glass powder include SiO₂—PbO-based, SiO₂—ZnO-based, SiO₂—Bi₂O₃-Based, SiO₂—K₂O-based, SiO₂—Na₂O-based, SiO₂—PbO—B₂O₃-Based, SiO₂—ZnO—B₂O₃-Based, SiO₂—Bi₂O₃—B2O₃-Based, SiO₂—K₂O—B₂O₃-based, and SiO₂—Na₂O—B₂O₃-Based glass.

Examples of the material for the ceramic powder include oxides, borides, nitrides, and silicides of metals. Examples of the metal are the same as those of the material for the metal powder. The ceramic powder may be a ferrite powder in which two or more metal oxides are compounded, or may be compounded with glass.

### Metal Resinate

The photosensitive paste according to the present disclosure may contain a metal resinate. The metal resinate is obtained by a reaction between metal and an organic substance. The metal resinate can reduce separation (delamination) between the wiring pattern and the insulating sheet during the firing step.

The metal resinate content may be 0.01 mass % or more or 0.1 mass % or more of the photosensitive resin composition. The metal resinate content may be 10 mass % or less or 5 mass % or less of the photosensitive resin composition. In one embodiment, the metal resinate content is 0.01 mass % or more and 10 mass % or less (i.e., from 0.01 mass % to 10 mass %) of the photosensitive resin composition.

The metal contained in the metal resinate may have a melting point higher than the inorganic powder. Examples of the metal contained in the metal resinate include rhodium (Rh), nickel (Ni), Cu, manganese (Mn), and zirconium (Zr).

Specific examples of the metal resinate include octylate salts, naphthenate salts, 2-ethylhexane salts, sulfonate salts, mercaptide, and alkoxide of the aforementioned metals.

### Solvent

The photosensitive paste according to the present disclosure may contain a solvent. Examples of the solvent include glycol organic solvents such as ethylene glycol monobutyl ether, ethylene glycol monohexyl ether, ethylene glycol monoethylhexyl ether, propylene glycol monobutyl ether, dipropylene glycol monoethyl ether, dipropylene glycol monobutyl ether, and propylene glycol monophenyl ether.

### Others

The photosensitive paste according to the present disclosure may contain various additives. Examples of the additives include a sensitizer, a defoaming agent, a dispersing agent, and an anti-settling additive.

### Method for Forming Wiring Pattern

Next, a method for forming a wiring pattern is described.

The wiring pattern is formed by a method that includes a step of forming a photosensitive paste film by applying the photosensitive conductive paste to an insulating sheet, a step of irradiating one portion of the photosensitive conductive paste film with an active energy ray, and a step of forming a wiring pattern by removing the uncured portion of the photosensitive conductive paste film.

### (1) Preparation of Insulating Sheet

First, an insulating sheet is prepared. The insulating sheet is, for example, prepared as follows. A paste having an insulating property (hereinafter referred to as an insulating paste) is applied by screen-printing to the entire surface of a supporting film, such as a PET film, and dried. If necessary, this printing and drying cycle is repeated multiple times. As a result, an insulating sheet having a specified thickness (for example, about 100 μm) is obtained.

The insulating paste typically contains an insulating inorganic powder. Typical examples of the insulating inorganic powder include glass powders and ceramic powders. The glass powder contained in the insulating paste may be a SiO₂—K₂O—B₂O₃-Based glass that contains SiO₂, K₂O, and B₂O₃ at particular ratios. Two or more glass powders may be used. The average particle size of the glass powder is not particularly limited, and is, for example, 0.8 μm or more and 1.3 μm or less (i.e., from 0.8 μm to 1.3 μm).

The ceramic powder contained in the insulating paste may be a metal oxide and may be aluminum oxide. Two or more ceramic powders may be used. The average particle size of the ceramic powder is not particularly limited, and may be, for example, 0.1 μm or more and 5.0 μm or less (i.e., from 0.1 μm to 5.0 μm).

The insulating sheet may be prepared by stacking green sheets preliminarily formed into a sheet shape.

### (2) Formation of Photosensitive Paste Film

The photosensitive conductive paste of the present disclosure is applied by screen-printing to the insulating sheet and dried. As a result, a photosensitive paste film is obtained. The thickness of the photosensitive paste film is not particularly limited, and may be, for example, 5 μm or more and 10 μm or less (i.e., from 5 μm to 10 μm).

### (3) Active Energy Ray Irradiation

One portion of the photosensitive paste film is irradiated with an active energy ray. During this process, a mask having openings is used. The mask partially blocks the active energy ray. Examples of the active energy ray include visible light, ultraviolet rays, infrared rays, X-rays, α rays, β rays, γ rays, and electron beams. In particular, the active energy ray may be UV rays and may be an UV ray having a peak wavelength in the range of 350 nm to 420 nm.

The integrated light intensity of the active energy ray is appropriately set according to the types and amounts of the photopolymerizable monomer and the photoinitiator, the thickness of the photosensitive paste film, etc. The integrated light intensity of the active energy ray may be, for example, 100 mJ/cm² or more and 2000 mJ/cm² or less (i.e., from 100 mJ/cm² to 2000 mJ/cm²).

### (4) Removal of Uncured Portion of Photosensitive Paste Film

Lastly, the uncured portion of the photosensitive paste film is removed. As a result, a wiring pattern formed of a cured photosensitive conductive paste is formed. The wiring pattern formed by the photosensitive conductive paste according to the present disclosure has excellent resolution.

An alkaline chemical is used to remove the uncured portion of the photosensitive paste film. As a result, the alkali-soluble polymer becomes soluble and is removed from the insulating sheet along with other components (the uncured photopolymerizable monomer, the polymerization initiator, the inorganic powder, etc.).

### Method for Producing Electronic Component

Next, a method for producing a multilayer coil component 10 is described.

The multilayer coil component 10 is produced by a method that includes a step of forming a photosensitive paste film by applying the photosensitive conductive paste to an insulating sheet, a step of irradiating one portion of the photosensitive paste film with an active energy ray, a step of removing the uncured portion of the photosensitive paste film to form a wiring pattern, a step of stacking an insulating sheet on the wiring pattern, a step of firing the wiring patterns and the insulating sheets to obtain insulating layers 40 as the sintered bodies of the insulating sheets and coil wires 2 as sintered bodies of the wiring patterns (cured photosensitive conductive paste).

The steps up to the formation of the wiring pattern are the same as the aforementioned (1) Preparation of insulating sheet, (2) Formation of photosensitive paste film, (3) Active energy ray irradiation, and (4) Removal of uncured portion of photosensitive paste film. In the method for producing the multilayer coil component 10, this cycle of steps (1) to (4) up to formation of the wiring pattern is performed multiple times.

In the second cycle, (1) Preparation of insulating sheet is performed as described above not on the supporting film but on the wiring pattern formed during the first cycle. As a result, the second insulating sheet is stacked. A via hole 3 is formed at a particular position of the second insulating sheet by laser beam irradiation.

Next, (2) Formation of photosensitive paste film, (3) Active energy ray irradiation, and (4) Removal of uncured portion of photosensitive paste film are again performed to form a second wiring pattern.

(1) Preparation of insulating sheet, formation of via holes 3, (2) Formation of photosensitive paste film, (3) Active energy ray irradiation, and (4) Removal of uncured portion of photosensitive paste film are repeated until the desired number layers are obtained.

Lastly, (1) Preparation of insulating sheet is repeated a required number of times to form insulating sheets on the uppermost wiring pattern. As a result, a multilayer structure that includes multiple insulating sheets and wiring patterns, in which interlayer connection is established between adjacent wiring patterns via the via holes 3, is obtained.

The obtained multilayer structure is divided into chips with a dicer. Subsequently, the supporting film used to prepare the first insulating sheet is separated.

### (5) Firing

Next, the chip-shaped multilayer structures are fired. As a result of firing, the wiring patterns become sintered into coil wires 2, and, at the same time, a coil 5 constituted by the coil wires 2 electrically connected to one another is formed. In addition, the insulating sheets become sintered and form an element body 4 that includes multiple insulating layers 40. The firing temperature is not particularly limited and may be appropriately set in view of the type of the material used, etc.

After firing, the first outer electrode 6a and the second outer electrode 6b are formed on the outer sides of the element body 4. As a result, a multilayer coil component 10 illustrated in FIG. 1 is obtained.

Furthermore, a plating layer having a single layer structure or a multilayer structure may be formed on each of the outer surfaces of the first outer electrode 6a and the second outer electrode 6b by electroplating or electroless plating.

### Second Embodiment

The second embodiment differs from the first embodiment in the type of radical scavenger contained in the photosensitive paste. This difference is described below. Other features of the second embodiment are the same as those of the first embodiment and the descriptions therefor are omitted. In the second embodiment, the structure of the electronic component, the method for forming the wiring pattern, and the method for producing the electronic component are the same as the first embodiment, and the descriptions therefor are omitted.

In this embodiment, the radical scavenger has a benzotriazole structure. A radical scavenger that has a benzotriazole structure (hereinafter may be referred to as a benzotriazole radical scavenger) facilitates even application of the photosensitive paste.

### Benzotriazole Radical Scavenger

The benzotriazole structure has a five-membered ring having three nitrogen atoms, and a benzene ring. The number of benzotriazole structures in one molecule is 1 or more and may be 2 or more. When two or more benzotriazole structures are present, they may be the same or different.

The benzotriazole radical scavenger is, for example, represented by general formula below:

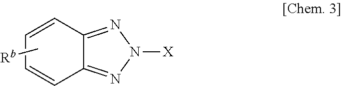

(In the formula, R^{b} represents one or more and four or less groups bonded to the benzene ring, and these groups may each independently represent a hydrogen atom, a hydroxyl group, a hydrocarbon group, a carboxy group, an amino group, or a halogen atom. X is a group bonded to the nitrogen atom and represents a hydrogen atom, a hydroxyl group, a hydrocarbon group, a carboxy group, an amino group, or a halogen atom.)

One or more R^{b} are bonded to the benzene ring, and two or more R^{b} may be bonded to the benzene ring. Four or less R^{b} are bonded to the benzene ring, and three or less R_{b} may be bonded to the benzene ring. When two or more R^{b} are present, they may be the same or different. R^{a} may be a hydrogen atom.

X typically has a phenol group. The phenol group is, for example, represented by general formula below:

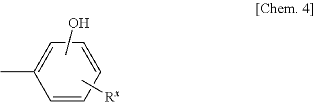

(In the formula, R^{x} represents one or more and four or less groups bonded to the benzene ring, and these groups may each independently represent a hydrogen atom, a hydroxyl group, a hydrocarbon group, a carboxy group, an amino group, or a halogen atom.)

One or more R^{x} are bonded to the benzene ring, and two or more R^{x} may be bonded to the benzene ring. Four or less R^{x} are bonded to the benzene ring, and three or less R^{x} may be bonded to the benzene ring. When two or more R^{x} are present, they may be the same or different.

At least one R^{x} may be an alkyl group, an alkyl group having 1 to 10 carbon atoms, or an alkyl group having 1 to 8 carbon atoms.

R& may have an alkyl ester group (—C(═O)O—R^{x1}). R^{x1} is, for example, a linear or branched alkyl group having 1 to 20 carbon atoms. The alkyl ester group may be directly bonded to the benzene ring, and, for example, may be bonded to the benzene ring via an alkyl group having 1 to 6 carbon atoms.

The benzene ring of the phenol group may be directly bonded to a nitrogen atom constituting the benzotriazole structure. As a result, changes in photocurability of the photosensitive paste over time can be reduced. A radical scavenger that has a benzotriazole structure and a phenol group can be deemed to be a benzotriazole radical scavenger.

The number of phenol groups in one molecule is 1 or more and may be 2 or more. The number and the type of the substituents (R^{x}) of the phenol groups may be the same or different.

The benzotriazole radical scavenger having a phenol group is, for example, represented by general formula below:

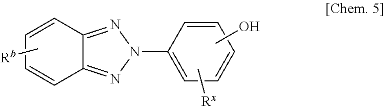

(In the formula, R^{b} and R^{x} are the same as above.)

Examples of the benzotriazole radical scavenger include 1,2,3-benzotriazole, 4-carboxy-1,2,3-benzotriazole, 5-carboxy-1,2,3-benzotriazole, methylbenzotriazole, carboxybenzotriazole, carboxymethylbenzotriazole, 1-[N,N-bis(2-ethylhexyl)aminomethyl]benzotriazole, 1-[N,N-bis(2-ethylhexyl)aminomethyl]methylbenzotriazole, and 2,2′-[[(methyl-1H-benzotriazol-1-yl)methyl]imino]bisethanol.

Examples of the benzotriazole radical scavenger having a phenol structure include 2-(2′-hydroxy-5′-methylphenyl)benzotriazole, 2-(2′-hydroxy-5′-tert-butylphenyl)benzotriazole, 2-(2′-hydroxy-3′,5′-di-tert-butylphenyl)benzotriazole, 2-(5-tert-butyl-2-hydroxyphenyl)benzotriazole, 2-(2-hydroxy-5-tert-octylphenyl)benzotriazole, 2-(2-hydroxy-3,5-di-tert-octylphenyl)benzotriazole, 2-[2′-hydroxy-3′,5′-bis((α,α′-dimethylbenzyl)phenyl]benzotriazole), a condensation product of methyl-3-[3-tert-butyl-5-(2H-benzotriazol-2-yl)-4-hydroxyphenyl]propionate and polyethylene glycol, a condensation product of bis{β-[3-(2H-benzotriazol-2-yl)-4-hydroxy-5-tert-butylphenyl]propionate and polyethylene glycol 300, isooctyl-3-[3-(2H-benzotriazol-2-yl)-5-tert-butyl-4-hydroxyphenyl]propionate, 2-(3-dodecyl-5-methyl-2-hydroxyphenyl)benzotriazole, 2-[2-hydroxy-5-(1,1,3,3-tetramethylbutyl)phenyl]benzotriazole, 2-(2′-hydroxy-3′-tert-butyl-5′-methylphenyl)-5-chlorobenzotriazole, 2-(2′-hydroxy-3′,5′-di-tert-amylphenyl)benzotriazole, 2-(2′-hydroxy-4′-octoxyphenyl)benzotriazole, 2-[2′-hydroxy-3′-(3″,4″,5″,6″-tetrahydrophthalimidomethyl)-5′-methylphenyl]benzotriazole, 2,2-methylenebis[4-(1,1,3,3-tetramethylbutyl)-6-(2H-benzotriazol-2-yl)phenol], 2-(2H-benzotriazol-2-yl)-4,6-bis(1-methyl-1-phenylethyl)phenol, 2-[2-hydroxy-5-[2-(methacryloyloxy)ethyl]phenyl]-2H-benzotriazole, and 6,6′-bis(2H-benzotriazol-2-yl)-4,4′-bis(2-hydroxyethyl)-2,2′-methylenediphenol.

### Third Embodiment

The third embodiment differs from the first embodiment in the type of radical scavenger contained in the photosensitive paste. This difference is described below. Other features of the third embodiment are the same as those of the first embodiment and the descriptions therefor are omitted. In the third embodiment, the structure of the electronic component, the method for forming the wiring pattern, and the method for producing the electronic component are the same as the first embodiment, and the descriptions therefor are omitted.

In this embodiment, the radical scavenger has a hindered amine structure. A radical scavenger that has a hindered amine structure (hereinafter may be referred to as a hindered amine radical scavenger) can reduce changes in viscosity of the photosensitive paste.

### Hindered Amine Radical Scavenger

The hindered amine structure has 2,2,6,6-tetramethylpiperidine as the basic skeleton.

The number of hindered amine structures in one molecule is 1 or more and may be 2 or more. When two or more hindered amine structures are present, they may be the same or different.

The hindered amine radical scavenger is, for example, represented by general formula below:

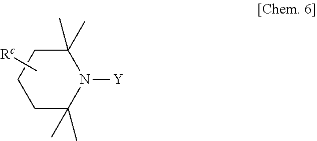

(In the formula, R^{c} represents one or more and three or less groups bonded to the piperidine ring, and these groups may each independently represent a hydrogen atom, a hydroxyl group, a hydrocarbon group, a carboxy group, an amino group, or a halogen atom, and Y represents a group bonded to the nitrogen atom and represents a hydrogen atom, a hydroxyl group, a hydrocarbon group, a carboxy group, an amino group, or a halogen atom.)

One or more R^{c} are bonded to the piperidine ring, and two or more R^{c} may be bonded to the piperidine ring. Three or less R^{c} are bonded to the piperidine ring. When two or more R^{c} are present, they may be the same or different.

At least one R^{c} may be a hydrocarbon group or a hydrocarbon group having a carbonyloxy structure. At least one R^{c} may be an amino group or a tertiary amino group.

Y is typically a hydrocarbon group. In this embodiment, Y represents an OR¹ group (R¹ represents a hydrocarbon group). R¹ may be an alkyl group having 1 to 20 carbon atoms or an alkyl group having 5 to 15 carbon atoms. R¹ may be linear. R¹ may be saturated.

The hindered amine radical scavenger that has the OR¹ group as Y is also referred to as an N—OR-type hindered amine. The radical scavenger which is an N—OR-type hindered amine improves the dispersibility of the inorganic powder in the photosensitive paste.

The N—OR-type hindered amine is, for example, represented by general formula below:

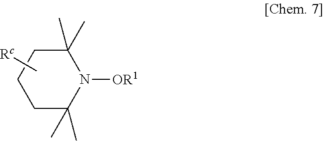

(In the formula, R^{c} is the same as above, and R¹ represents a hydrocarbon group.)

Specific examples of the N—OR-type hindered amine include a reaction product of bis(2,2,6,6-tetramethyl-4-piperidyl)=decanedioate, 2-hydroperoxy-2-methylpropane, and octane, bis[2,2,6,6-tetramethyl-1-(undecyloxy)piperidin-4-yl]=carbonate, and 2,4-bis[N-butyl-N-(1-cyclohexyloxy-2,2,6,6-tetramethylpiperidic-4-yl)amino]-6-(2- hydroxyethylamine)-1,3,5-triazine.

### Modification Example 1

In a modification example of the present embodiment, Y represents a COR² group (R² represents a hydrocarbon group). R² may be an alkyl group having 1 to 6 carbon atoms, an alkyl group having 1 to 3 carbon atoms, or a methyl group.

The hindered amine radical scavenger that has the COR² group as Y is also referred to as an N—COR-type hindered amine. The radical scavenger which is an N—COR-type hindered amine improves the wettability of the photosensitive paste to the substrate.

The N—COR-type hindered amine is, for example, represented by general formula below:

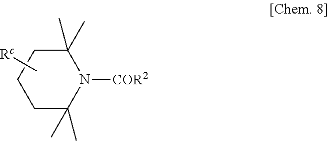

(In the formula, R^{c} is the same as above, and R² represents a hydrocarbon group.)

A specific example of the N—COR-type hindered amine is 1-(1-acetyl-2,2,6,6-tetramethyl-4-piperidyl)-3-dodecylpyrrolidine-2,5-dione.

### Modification Example 2

In another modification example of the present embodiment, Y represents an R³ group (R³ represents an alkyl group directly bonded to the nitrogen atom). R³ may be an alkyl group having 1 to 6 carbon atoms, an alkyl group having 1 to 3 carbon atoms, or a methyl group.

The hindered amine radical scavenger that has the R³ group as Y is also referred to as an N—R-type hindered amine. The radical scavenger which is an N—R-type hindered amine improves the degree of freedom of setting the development time.

The N—R-type hindered amine is, for example, represented by general formula below:

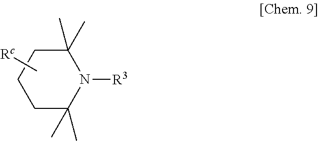

(In the formula, R^{c} is the same as above, and R³ represents an alkyl group directly bonded to the nitrogen atom.)

The N—R-type hindered amine having a methyl group represented by R³ is, for example, represented by general formula below:

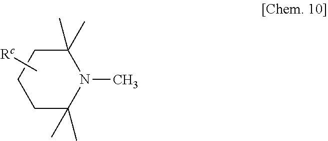

(In the formula, R^{c} is the same as above.)

Specific examples of the N—R-type hindered amine include bis(1,2,2,6,6-pentamethyl-4-piperidyl) sebacate, bis(1,2,2,6,6-pentamethyl-4-piperidyl) 2-(3,5-di-tert-butyl)-4-hydroxybenzyl)-2-butylmalonate, and bis(1,2,2,6,6-pentamethyl-4-piperidyl)-[[3,5-bis(1,1-dimethylethyl-4-hydroxy phenyl]methyl]butylmalonate, and a mixture of bis(1,2,2,6,6-pentamethyl-4-piperidyl) sebacate and methyl-1,2,2,6,6-pentamethyl-4-piperidyl-sebacate.

### EXAMPLES

The present disclosure will now be described in further details through examples below which do not limit the present disclosure. In these examples, “parts” and “%” are on a mass basis unless otherwise noted.

### Example 1

### 1 Preparation of Photosensitive Conductive Paste

Raw materials indicated in Table 1 were thoroughly mixed to obtain a photosensitive resin composition.

TABLE 1

| | Content in |
|---|---|
| | photosensitive |
| Components | resin (parts) |
| Alkali-soluble polymer (acrylic polymer having | 39 |
| a carboxy group in a side chain) | |
| Photosensitive monomer (polyfunctional acrylate | 18 |
| monomer) | |
| Photoinitiator (α-hydroxyalkylphenone compound) | 4 |
| Solvent (glycol organic solvent) | 38 |
| Defoaming agent | 1 |

22.7 parts of the photosensitive resin composition, 77.0 parts of an inorganic powder (Ag powder with an average particle size of 1.5 μm), and 0.3 parts of a radical scavenger A (2,5-di-tert-butylbenzene-1,4-diol) were blended and thoroughly mixed with three rolls to obtain a photosensitive conductive paste.

The structural formula of the radical scavenger A (2,5-di-tert-butylbenzene-1,4-diol) used in Example 1 is as follows.

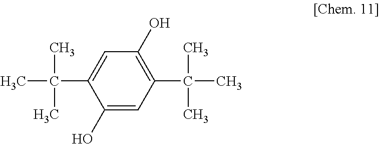 [SMILES: CC(C)(C)c1cc(O)c(C(C)(C)C)cc1O]

### 2 Preparation of Wiring Pattern

The obtained photosensitive conductive paste was applied to an insulating layer (1 mm-thick alumina substrate) by screen-printing and dried at 60° C. for 30 minutes to form a photosensitive conductive paste film having a thickness of 8 μm.

A photomask having a straight-line pattern (width of the straight-line opening: 15 μm, intervals between openings: 45 μm) was prepared. The obtained photosensitive conductive paste film was irradiated with an active energy ray (UV ray having a peak wavelength in the wavelength range of 350 nm to 420 nm) through the aforementioned photomask under the condition of integrated light intensity of 1500 mJ/cm².

Lastly, the uncured portion of the photosensitive conductive paste film was removed by using an aqueous triethanol amine solution to obtain a wiring pattern.

### Example 2

A photosensitive conductive paste was prepared and a wiring pattern was obtained as in Example 1 except that a radical scavenger B (4-methoxyphenol) represented by structural formula below was used instead of the radical scavenger A.

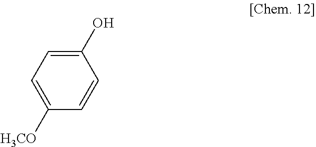

### Example 3

A photosensitive conductive paste was prepared and a wiring pattern was obtained as in Example 1 except that a radical scavenger C (1,3,5-tris[(4-tert-butyl-3-hydroxy-2,6-dimethylbenzyl)methyl]-1,3,5-triazine-2,4,6(1H,3H,5H)-trion) represented by structural formula below was used instead of the radical scavenger A.

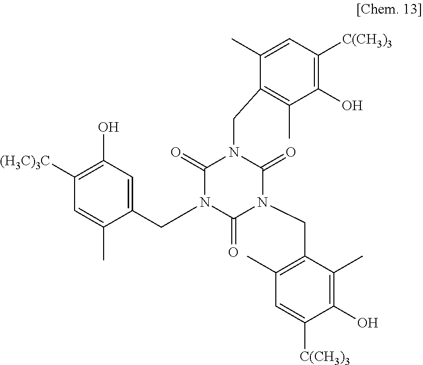 [SMILES: Cc1cc(C(C)(C)C)c(O)cc1Cn1c(=O)n(Cc2c(C)cc(C(C)(C)C)c(O)c2C)c(=O)n(Cc2c(C)cc(C(C)(C)C)c(O)c2C)c1=O]

### Example 4

A photosensitive conductive paste was prepared and a wiring pattern was obtained as in Example 1 except that a radical scavenger D (1,2,3-benzotriazole) represented by structural formula below was used instead of the radical scavenger A.

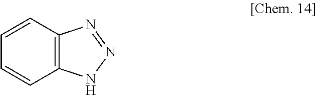

### Example 5

A photosensitive conductive paste was prepared and a wiring pattern was obtained as in Example 1 except that a radical scavenger E (2-(2′-hydroxy-5′-methylphenyl)benzotriazole) represented by structural formula below was used instead of the radical scavenger A.

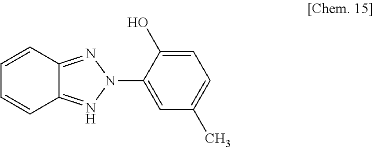 [SMILES: Cc1ccc(O)c(-n2nc3ccccc3n2)c1]

### Example 6

A photosensitive conductive paste was prepared and a wiring pattern was obtained as in Example 1 except that a radical scavenger F (2-[2-hydroxy-5-(1,1,3,3-tetramethylbutyl)phenyl]benzotriazole) represented by structural formula below was used instead of the radical scavenger A.

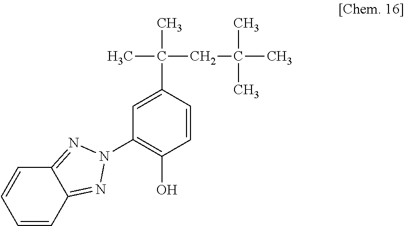 [SMILES: CC(C)(C)CC(C)(C)c1ccc(O)c(-n2nc3ccccc3n2)c1]

### Example 7

A photosensitive conductive paste was prepared and a wiring pattern was obtained as in Example 1 except that a radical scavenger G (bis[2,2,6,6-tetramethyl-1-(undecyloxy)piperidin-4-yl]=carbonate) represented by structural formula below was used instead of the radical scavenger A.

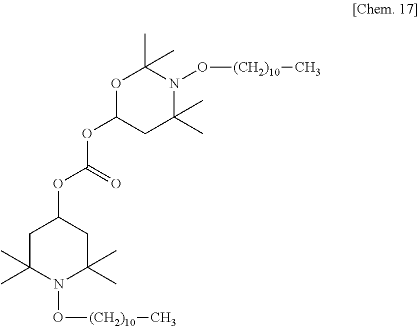

### Example 8

A photosensitive conductive paste was prepared and a wiring pattern was obtained as in Example 1 except that a radical scavenger H (reaction product of bis(2,2,6,6-tetramethyl-4-piperidyl)=decanedioate, 2-hydroperoxy-2-methylpropane, and octane) represented by structural formula below was used instead of the radical scavenger A.

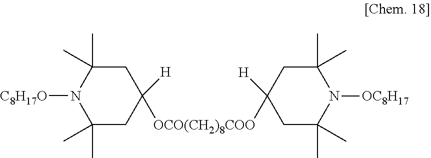

### Example 9

A photosensitive conductive paste was prepared and a wiring pattern was obtained as in Example 1 except that a radical scavenger I (1-(1-acetyl-2,2,6,6-tetramethyl-4-piperidyl)-3-dodecylpyrrolidine-2,5-dione) represented by structural formula below was used instead of the radical scavenger A.

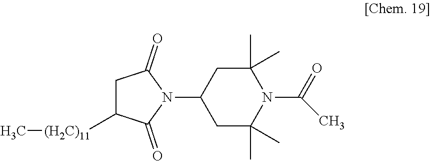

### Example 10

A photosensitive conductive paste was prepared and a wiring pattern was obtained as in Example 1 except that a radical scavenger J (bis(1-octoxy-2,2,6,6-tetramethyl-4-piperidyl) sebacate) represented by structural formula below was used instead of the radical scavenger A.

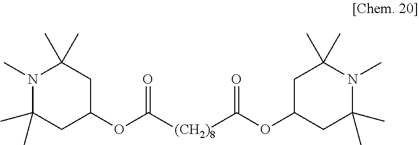

### Comparative Example 1

A photosensitive conductive paste was prepared and a wiring pattern was obtained as in Example 1 except that the radical scavenger A was not blended.

### Evaluation of Resolution

The obtained wiring pattern was observed with a confocal microscope (Optelics produced by Lasertec Corporation), the width of the straight-line portion was measured at arbitrarily selected five points, and the average value X (μm) was calculated. The evaluation result is indicated in Table 2. The smaller the difference between the average value X of the line width and 15 μm, which was the width of the straight-line opening, the better the resolution.

TABLE 2

| | Radical scavenger | X − 15 (μm) |
|---|---|---|
| Example 1 | A: hindered phenol | −2 |
| Example 2 | B: phenol-based | 1 |
| Example 3 | C: phenol-based | 2 |
| Example 4 | D: benzotriazole-based | 12 |
| Example 5 | E: phenol group-containing benzotriazole | 11 |
| Example 6 | F: phenol group-containing benzotriazole | 13 |
| Example 7 | G: N-OR-type hindered amine | 11 |
| Example 8 | H: N-OR-type hindered amine | 11 |
| Example 9 | I: N-COR-type hindered amine | 11 |
| Example 10 | J: N-R-type hindered amine | 12 |
| Comparative | — | 15 |
| Example 1 | | |

The difference (X−15) between the width of the wiring pattern prepared from the photosensitive conductive paste and the width of the opening in the mask was smaller than the width (15 mm) of the opening in all of Examples, and the resolution was excellent in all of Examples. Meanwhile, the difference (X−15) between the width of the wiring pattern prepared from the photosensitive conductive paste and the width of the opening in the mask was equal to or larger than the width (15 mm) of the opening in Comparative Example, and the resolution was inferior in Comparative Example.

The present disclosure is not limited to the aforementioned embodiments, and is subject to design modifications and alterations without departing from the gist of the present disclosure. For example, the radical scavengers used in the first to third embodiments may be combined in a variety of ways.

In the first to third embodiments, the photosensitive paste has electrical conductivity; alternatively, the photosensitive paste of the present disclosure may be non-electrically conductive. The non-electrically conductive photosensitive paste is used in, for example, forming insulating films of electronic components.

In the first to third embodiments, the electronic component includes multiple coil wires; alternatively, the number of coil wires may be one.

In the first to third embodiments, a coil component was prepared by using an electrically conductive photosensitive paste according to the present disclosure; alternatively, the usage of the conductive photosensitive paste is not limited to this.

The electrically conductive photosensitive paste according to the present disclosure is used in producing circuit boards such as multilayer ceramic substrates, active components, and passive components other than coil components. Active components are components that, for example, amplify, rectify, and convert power supplied. Examples of the active components include transistors and various sensors. Passive components are components that consume, store, or release power supplied, and refer to components that do not perform active operations such as amplification and rectification. Examples of the passive components include, in addition to coil components, resistors, capacitors, and thermistors.

The present disclosure includes the following embodiments.
<1> A photosensitive paste comprising a photoinitiator; a photopolymerizable monomer; an alkali-soluble polymer; an inorganic powder; and a radical scavenger.
<2> The photosensitive paste described in <1>, wherein the inorganic powder has electrical conductivity.
<3> The photosensitive paste described in <1> or <2>, wherein the radical scavenger has a phenol structure.
<4> The photosensitive paste described in <3>, wherein the radical scavenger having a phenol structure further has at least one of a tert-butyl group or an alkoxy group bonded to a benzene ring constituting the phenol structure.
<5> The photosensitive paste described in <1> or <2>, wherein the radical scavenger has a benzotriazole structure.
<6> The photosensitive paste described in <5>, wherein the radical scavenger having a benzotriazole structure further has a phenol group bonded to a nitrogen atom constituting the benzotriazole structure.
<7> The photosensitive paste described in <1> or <2>, wherein the radical scavenger has a hindered amine structure.
<8> The photosensitive paste described in <7>, wherein the radical scavenger having a hindered amine structure has an OR¹ group bonded to a nitrogen atom constituting the hindered amine structure (R¹ represents a hydrocarbon group).
<9> The photosensitive paste described in <7>, wherein the radical scavenger having a hindered amine structure has a COR² group bonded to a nitrogen atom constituting the hindered amine structure (R² represents a hydrocarbon group).
<10> The photosensitive paste described in <7>, wherein the radical scavenger having a hindered amine structure has an R³ group bonded to a nitrogen atom constituting the hindered amine structure (R³ represents an alkyl group directly bonded to the nitrogen atom).
<11> The photosensitive paste described in <2> and any one of <3> to <10> dependent on <2>, wherein the photosensitive paste is used in forming a wiring pattern.
<12> A method for forming a wiring pattern, the method comprising a step of forming a photosensitive paste film by applying the photosensitive paste described in <2> and any one of <3> to <10> dependent on <2> to an insulating sheet; a step of irradiating a portion of the photosensitive paste film with an active energy ray; and a step of forming a wiring pattern by removing an uncured portion of the photosensitive paste film.
<13> A method for producing an electronic component, the method comprising a step of forming a photosensitive paste film by applying the photosensitive paste described in <2> and any one of <3> to <10> dependent on <2> to an insulating sheet; a step of irradiating a portion of the photosensitive paste film with an active energy ray; a step of forming a wiring pattern by removing an uncured portion of the photosensitive paste film; a step of stacking an insulating sheet on the wiring pattern; and a step of firing the wiring pattern and the insulating sheets to obtain a plurality of insulating layers as sintered bodies of the plurality of insulating sheets and an inner wire as a sintered body of the wiring pattern.
<14> An electronic component comprising an element body including a plurality of insulating layers; and an inner wire that is a sintered body of a cured product of the photosensitive paste described in <2> and any one of <3> to <10> dependent on <2>, the inner wire being disposed in the element body.

What is claimed is:

1. A photosensitive paste comprising:
a photoinitiator;
a photopolymerizable monomer;
an alkali-soluble polymer;
an inorganic powder; and
a radical scavenger.

2. The photosensitive paste according to claim 1, wherein
the inorganic powder has electrical conductivity.

3. The photosensitive paste according to claim 1, wherein
the radical scavenger has a phenol structure.

4. The photosensitive paste according to claim 3, wherein
the radical scavenger having a phenol structure further has at least one of a tert-butyl group or an alkoxy group bonded to a benzene ring constituting the phenol structure.

5. The photosensitive paste according to claim 1, wherein
the radical scavenger has a benzotriazole structure.

6. The photosensitive paste according to claim 5, wherein
the radical scavenger having a benzotriazole structure further has a phenol group bonded to a nitrogen atom constituting the benzotriazole structure.

7. The photosensitive paste according to claim 1, wherein
the radical scavenger has a hindered amine structure.

8. The photosensitive paste according to claim 7, wherein
the radical scavenger having a hindered amine structure has an OR¹ group bonded to a nitrogen atom constituting the hindered amine structure (R¹ represents a hydrocarbon group).

9. The photosensitive paste according to claim 7, wherein
the radical scavenger having a hindered amine structure has a COR² group bonded to a nitrogen atom constituting the hindered amine structure (R² represents a hydrocarbon group).

10. The photosensitive paste according to claim 7, wherein
the radical scavenger having a hindered amine structure has an R³ group bonded to a nitrogen atom constituting the hindered amine structure (R³ represents an alkyl group directly bonded to the nitrogen atom).

11. The photosensitive paste according to claim 2, wherein
the photosensitive paste is used in configuring a wiring pattern.

12. A method for forming a wiring pattern, the method comprising:
forming a photosensitive paste film by applying the photosensitive paste according to claim 2 to an insulating sheet;
irradiating a portion of the photosensitive paste film with an active energy ray; and
forming a wiring pattern by removing an uncured portion of the photosensitive paste film.

13. A method for producing an electronic component, the method comprising:
forming a photosensitive paste film by applying the photosensitive paste according to claim 2 to an insulating sheet;
irradiating a portion of the photosensitive paste film with an active energy ray;
forming a wiring pattern by removing an uncured portion of the photosensitive paste film;
stacking an insulating sheet on the wiring pattern; and
firing the wiring pattern and the insulating sheets to obtain a plurality of insulating layers as sintered bodies of the plurality of insulating sheets and an inner wire as a sintered body of the wiring pattern.

14. An electronic component comprising:
an element body including a plurality of insulating layers; and
an inner wire that is a sintered body of a cured product of the photosensitive paste according to claim 2, the inner wire being in the element body.

15. The photosensitive paste according to claim 2, wherein
the radical scavenger has a phenol structure.

16. The photosensitive paste according to claim 2, wherein
the radical scavenger has a benzotriazole structure.

17. The photosensitive paste according to claim 2, wherein
the radical scavenger has a hindered amine structure.
